(19) United States
(12) Patent Application Publication
(10) Pub. No.: US 2010/0032768 A1
(43) Pub. Date: Feb. 11, 2010

(54) TRANSISTOR OF IMAGE SENSOR AND METHOD FOR MANUFACTURING THE SAME

(75) Inventor: Hyung-Jin Park, Eumseonggun (KR)

Correspondence Address: SHERR & VAUGHN, PLLC, 620 HERNDON PARKWAY, SUITE 320, HERNDON, VA, 20170, US

(73) Assignee: Dongbu HiTeck Co., Ltd., Seoul (KR)

(21) Appl. No.: 12/537,189

(22) Filed: Aug. 6, 2009

(30) Foreign Application Priority Data
Aug. 6, 2008 (KR) 10-2008-0076953

(51) Int. Cl. H01L 27/06; H01L 21/8249

(52) U.S. Cl. 257/378; 438/207; 257/E27.015; 257/E21.696; 438/234

(57) ABSTRACT

A transistor of an image sensor and a method for manufacturing the same include simultaneously forming a device isolation layer at a boundary between a first conductive transistor region having a second conductive well formed therein and a second conductive transistor region having a first conductive well formed therein, and a trench dielectric layer at a junction transistor region having no conductive well formed therein, and then simultaneously forming a first gate pattern at the first conductive transistor region, a second gate pattern at the second conductive transistor region and a laminated layer at the junction transistor region, and then forming a bipolar junction in the laminated layer by sequentially implanting a first conductive dopant and a second conductive dopant into the laminated layer.

The present application claims priority under 35 U.S.C. §119 to Korean Patent Application No. P10-2008-0076953, filed on Aug. 6, 2008, which is hereby incorporated by reference in its entirety.

### BACKGROUND

Generally, image sensors are semiconductor devices which convert an optical image into electric signals. A complementary metal oxide semiconductor (CMOS) image sensor adopts a signal switching method, whereby MOS transistors equal in number to the number of pixels are made and used to detect output signals in sequence by way of a CMOS technique that uses a control circuit and a signal processing circuit as peripheral circuits. In the CMOS image sensor, each unit pixel includes a photodiode and a MOS transistor to detect signals in a switching manner, thus forming images. In general, the MOS transistor is an N-channel MOS (NMOS) transistor or a P-channel MOS (PMOS) transistor.

A bipolar junction transistor (hereinafter, referred to as “BJT”) has better device-to-device matching characteristics than the above-described MOS transistor. Also, a BJT has a 1/f noise that is much smaller than that of the MOS transistor by a hundred times or more, thus effectively solving deterioration in system noise characteristics due to the presence of DC offset problems and 1/f noise. Thereby, a BiCMOS has been developed, in which a CMOS image sensor and a BJT are integrated together.

FIG. 1 is a sectional view illustrating a transistor configuration of a BiCMOS. To solve problematic device characteristics of a MOS transistor, a vertical parasitic BJT may be used. However, heretofore, a majority of BJTs are of an NPN-type or a PNP-type derived from a well structure. In this case, there is a problem in that isolation between different conductive type wells is difficult. To solve this problem, technical complementary measures are necessary to form a deep trench or a buried layer.

### SUMMARY

Embodiments relate to a transistor of an image sensor and a method for manufacturing the same which are suitable to the manufacture of a BJT used in a CMOS image sensor by way of CMOS processes.

Embodiments relate to a transistor of an image sensor and a method for manufacturing the same are provided in which a BJT for use in a CMOS image sensor is formed without using a well in order to realize perfect isolation between different conductive type wells.

In accordance with embodiments, a method for manufacturing a transistor of an image sensor may include at least one of the following: forming a device isolation layer on and/or over a boundary between a first conductive transistor region and a second conductive transistor region of a semiconductor substrate and a trench dielectric layer in a junction transistor region of the semiconductor substrate; and then forming a first conductive well in the second conductive transistor region of the semiconductor substrate and a second conductive well in the first conductive transistor region of the semiconductor substrate; and then forming a gate pattern of a first conductive transistor on and/or over the second conductive well of the first conductive transistor region, a gate pattern of a second conductive transistor on and/or over the first conductive well of the second conductive transistor region, and a laminated layer having the same lamination configuration as the gate patterns on the trench dielectric layer of the junction transistor region; and then forming a bipolar junction on and/or over the laminated layer by sequentially implanting a first conductive dopant and a second conductive dopant into the laminated layer; and then forming contacts to be connected to respective junctions of the bipolar junction.

In accordance with embodiments, a transistor of an image sensor may include at least one of the following: a semiconductor substrate; a first conductive transistor formed in a first conductive transistor region of the semiconductor substrate; a second conductive transistor formed in a second conductive transistor region of the semiconductor substrate; a device isolation layer formed on and/or over a boundary between the first conductive transistor region and the second conductive transistor region of the semiconductor substrate; a trench dielectric layer formed in a junction transistor region of the semiconductor substrate; and a bipolar junction formed on and/or over the trench dielectric layer by sequentially implanting first conductive dopant and second conductive dopant into a laminated layer having the same lamination configuration as gate patterns of the first and second conductive transistors.

In accordance with embodiments, a method may include at least one of the following: providing a semiconductor substrate having a junction transistor region, a first conductive well formed in a second conductive transistor region of the semiconductor substrate and a second conductive well in a first conductive transistor region of the semiconductor substrate; and then simultaneously forming a device isolation layer at a boundary between the first conductive transistor region and the second conductive transistor region and a trench dielectric layer in the junction transistor region; and then simultaneously forming a first gate pattern of a first conductive transistor over the second conductive well, a second gate pattern of a second conductive transistor over the first conductive well and a laminated layer over the trench dielectric layer having the same lamination configuration as the first and second gate patterns; and then forming a bipolar junction over the laminated layer by sequentially implanting a first conductive dopant and a second conductive dopant into the laminated layer; and then forming contacts connected to respective junctions of the bipolar junction.

In accordance with embodiments, a method may include at least one of the following: simultaneously forming a device isolation layer at a boundary between a first conductive transistor region having a second conductive well formed therein and a second conductive transistor region having a first conductive well formed therein, and a trench dielectric layer at a junction transistor region having no conductive well formed therein; and then simultaneously forming a first gate pattern at the first conductive transistor region, a second gate pattern at the second conductive transistor region and a laminated layer at the junction transistor region; and then forming a bipolar junction in the laminated layer by sequentially implanting a first conductive dopant and a second conductive dopant into the laminated layer.

In accordance with embodiments, a transistor for an image sensor may include at least one of the following: a semiconductor substrate having a junction transistor region having no well formed therein, a second conductive transistor region having a first conductive well formed therein, and a first conductive transistor region having a second conductive well formed therein; a first conductive transistor formed over the second conductive well in the first conductive transistor region; a second conductive transistor formed over the first conductive well in the second conductive transistor region; a device isolation layer formed at a boundary between the first conductive transistor region and the second conductive transistor region; a trench dielectric layer formed in the junction transistor region; a junction transistor formed over the trench dielectric layer of the junction transistor region; a bipolar junction formed in the junction transistor.

### DRAWINGS

FIG. 1 illustrates a transistor configuration of a BiCMOS.

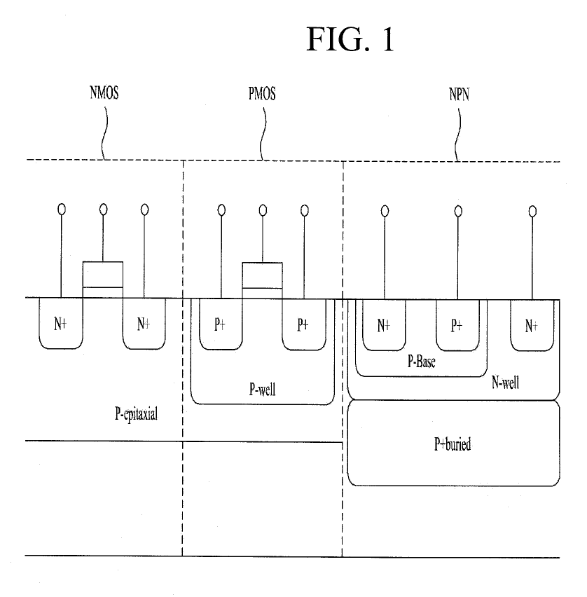

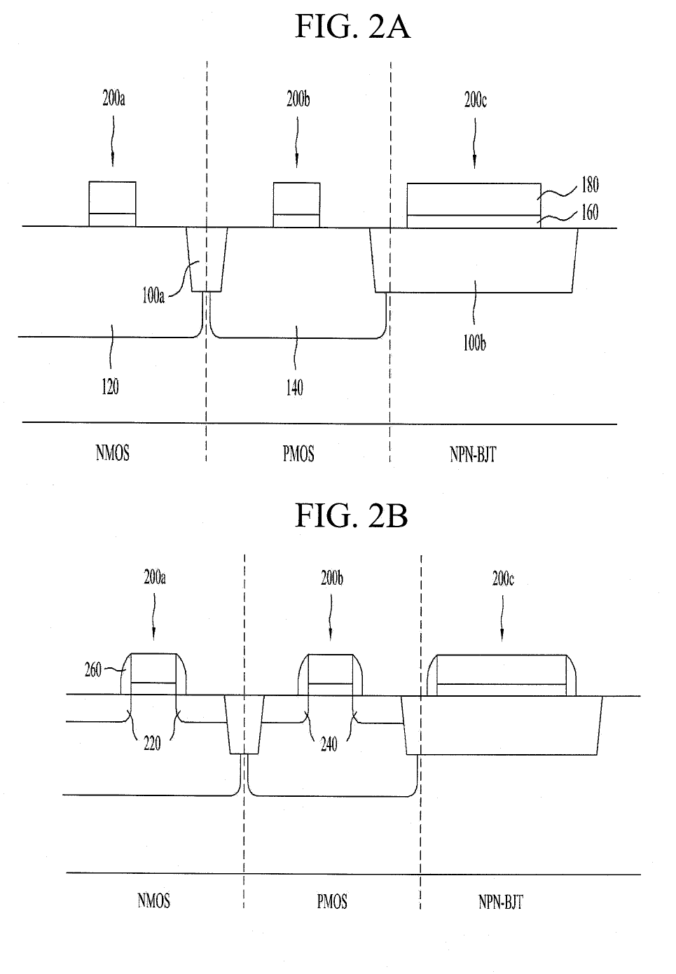

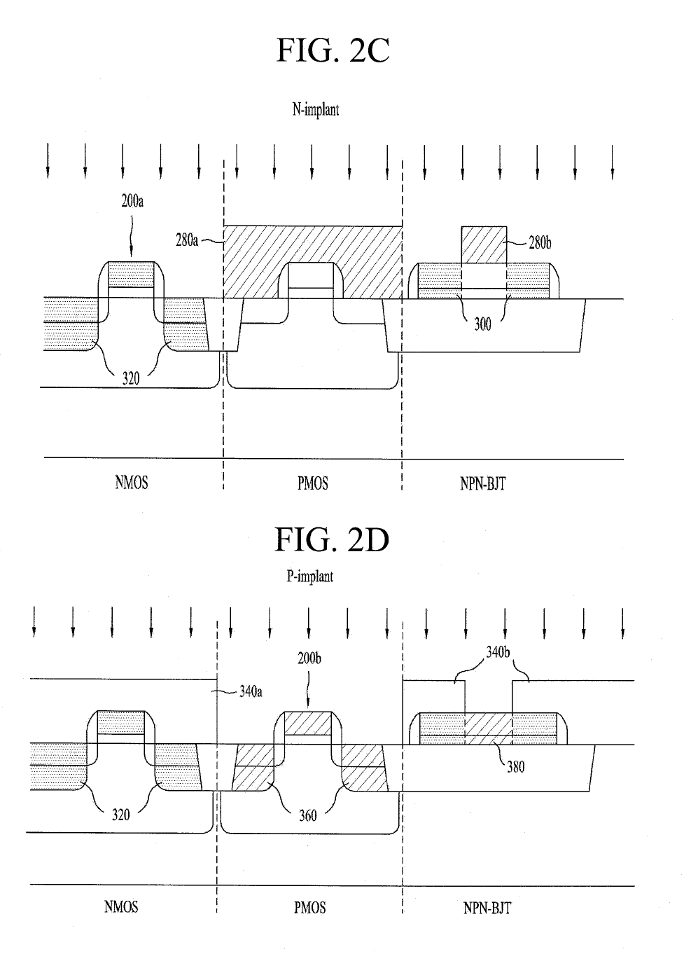

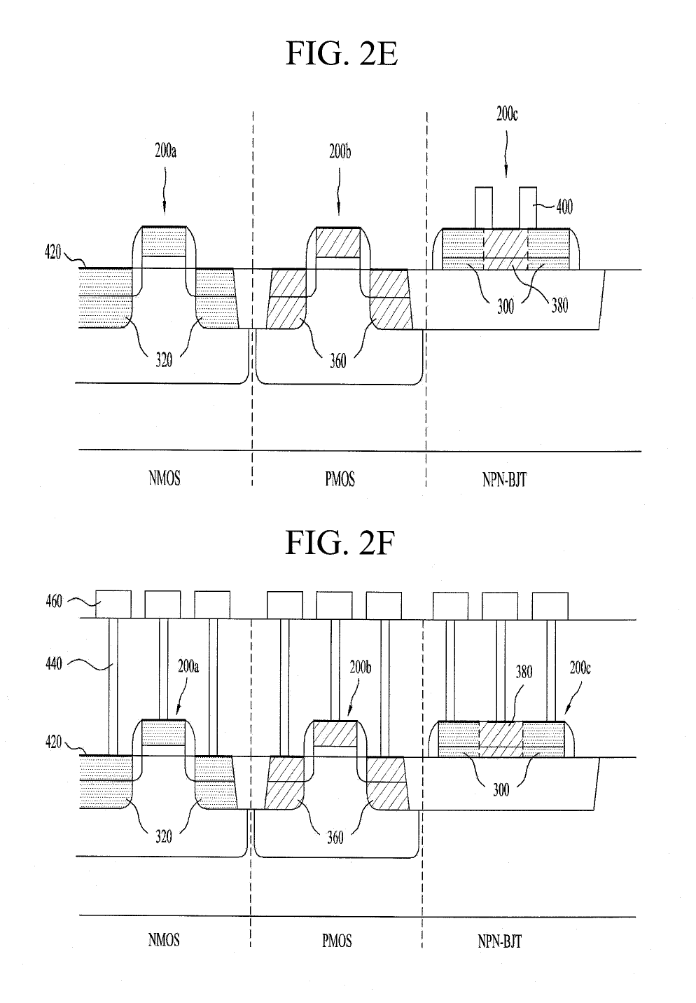

Example FIGS. 2A to 2F illustrate a method for manufacturing a transistor of a CMOS image sensor in accordance with embodiments.

### DESCRIPTION

Reference will now be made in detail to preferred embodiments, examples of which are illustrated in the accompanying drawings. Wherever possible, the same reference numbers will be used throughout the drawings to refer to the same or like parts. In the following description, although configurations and operations of embodiments will be described by way of example with reference to the accompanying drawings, their scope and spirit are not limited thereto.

Hereinafter, a transistor of an image sensor and a method for manufacturing the same in accordance with embodiments will be described in detail with reference to the accompanying drawings. In particular, in the following description, a CMOS image sensor will be described as an image sensor by way of example.

The transistor of the CMOS image sensor in accordance with embodiments is provided in a transistor region, and may be a BiCMOS transistor that includes an N-channel MOS (NMOS) transistor, a P-channel MOS (PMOS) transistor, and a bipolar junction transistor (BJT). The NMOS transistor is provided in an NMOS transistor region NMOS of a semiconductor substrate, the PMOS transistor is provided in a PMOS transistor region PMOS of the semiconductor substrate, and the BJT is provided in a BJT region NPN-BJT of the semiconductor substrate. Hereinafter, an NPN-type BJT will be described as the BJT by way of example.

The semiconductor device in accordance with embodiments includes device isolation layer 100a formed at a boundary between the NMOS transistor region NMOS and the PMOS transistor region PMOS to isolate the regions NMOS and PMOS from each other. Device isolation layer 100a may be formed by a shallow trench isolation (STI) process and may be simultaneously formed with trench dielectric layer 100b provided in the BJT region NPN-BJT. Trench dielectric layer 100b may be formed by an STI process, and may be composed as an oxide layer. P-type well 120 is provided in the NMOS transistor region NMOS of the semiconductor substrate, in which an NMOS transistor will be formed. N-type well 140 is provided in the PMOS transistor region PMOS of the semiconductor substrate, in which a PMOS transistor will be formed.

First gate pattern 200a of the NMOS transistor is provided on and/or over P-type well 120 of the NMOS transistor region NMOS, and second gate pattern 200b of the PMOS transistor is provided on and/or over N-type well 140 of the PMOS transistor region PMOS. First gate pattern 200a and second gate pattern 200b are formed as a gate poly in which gate oxide layer 160 and poly silicon layer 180 are sequentially stacked one above another. Spacer 260 is provided on and/or over side walls of the gate poly. First lightly doped drains (LDDs) 220 into which N-type dopant is implanted are provided around first gate pattern 200a of the NMOS transistor. Second lightly doped drains (LDDs) 240 into which P-type dopant is implanted are provided around second gate pattern 200b of the PMOS transistor. First LDDs 200 are provided in P-type well 120 of the NMOS transistor, and second LDDs 240 are provided in N-type well 140 of the PMOS transistor. However, the occupation area of first LDDs 220 and/or second LDDs 240 is reduced due to first source/drain 320 and/or second source/drain 360 that will be formed later in the respective wells 120 and 140. First LDDs 220 and second LDDs 240 overlap with spacers 260 of the respective gate patterns 200a and 200b.

First source/drain 320 into which N-type dopant is implanted is formed around first gate pattern 200a of the NMOS transistor including spacer 260. Second source/drain 360 into which P-type dopant is implanted is formed around second gate pattern 200b of the PMOS transistor including spacer 260. First source/drain 320 of the NMOS transistor is formed in P-type well 120 of the NMOS transistor at a greater depth than first LDDs 220. Second source/drain 360 of the PMOS transistor is formed in N-type well 140 of the PMOS transistor at a greater depth than second LDDs 240.

Laminated layer 200i c is provided in the BJT region on and/or over trench dielectric layer 100b, which is formed simultaneously with formation of first gate pattern 200a of the NMOS transistor and second gate pattern 200b of the PMOS transistor. Specifically, when gate oxide layer 160 and poly silicon layer 180 are sequentially stacked one another on and/or over P-type well 120 and N-type well 140 and are patterned to form first gate pattern 200a and second gate pattern 200b, laminated layer 200c is formed having the same lamination configuration as first gate pattern 200a and second gate pattern 200b. However, a pattern width of laminated layer 200c may be greater than the respective widths of first gate pattern 200a and second gate pattern 200b. Spacer 260 may also be provided on and/or over side walls of laminated layer 200c. Spacers 260 may be simultaneously formed on and/or over laminated layer 200c, first gate pattern 200a and second gate pattern 200b.

Laminated layer 200c thus forms an NPN-type BJT. In particular, the NPN-type BJT is formed by sequentially implanting N-type dopant and P-type dopant into laminated layer 200c. Center P-type junction 380 is formed during implantation for formation of second source/drain 360 of the PMOS transistor. N-type junctions 300 at opposite sides of P-type junction 380 are formed during implantation for formation of first source/drain 320 of the NMOS transistor.

Alternatively, the P-type dopant may be implanted into the poly silicon layer included in second gate pattern 200b of the PMOS transistor during implantation for formation of second source/drain 360 of the PMOS transistor. The N-type dopant may be implanted into the poly silicon layer included in first gate pattern 200a of the NMOS transistor during implantation for formation of source/drain 320 of the NMOS transistor.

Salicide layer 420 is formed on and/or over N-type junction junction 300 and P-type junction 380 of the NPN-type BJT, first gate pattern 200a and first source/drain 320 of the NMOS transistor, and second gate pattern 200b and second source/drain 360 of the PMOS transistor. An inter metal dielectric layer may be provided on and/or over the entire surface of the semiconductor substrate. The inter metal dielectric layer may include contacts 440 extending therethrough and which are connected to N-type junction 300 and P-type junction 380 of the NPN-type BJT, first gate pattern 200a and first source/drain 320 of the NMOS transistor, and second gate pattern 200b and second source/drain 360 of the PMOS transistor. Metal lines 460 may be provided on and/or over the inter metal dielectric layer at positions corresponding to contacts 440.

The manufacturing procedure of the transistor of the CMOS image sensor having the above-described configuration will be described with reference to example FIGS. 2A to 2F.

As illustrated in example FIG. 2A, device isolation layer 100a is formed at the boundary between the NMOS transistor region NMOS and the PMOS transistor region PMOS of a semiconductor substrate to isolate the regions NMOS and PMOS from each other. Simultaneously with formation of device isolation layer 100a, trench dielectric layer 100b is formed in the BJT region NPN-BJT. Both device isolation layer 100a and trench dielectric layer 100b are formed by a shallow trench isolation (STI) process. For instance, a first trench is formed in the boundary between the NMOS transistor region NMOS and the PMOS transistor region PMOS of the semiconductor substrate and a second trench is simultaneously formed in the BJT region NPN-BJT. Subsequently, dielectrics material(s) such as oxides, are buried in the first and second trenches, thus simultaneously forming device isolation layer 100a in the first trench and trench dielectric layer 100b in the second trench. In particular, the second trench may be formed in the entire surface of the BJT region NPN-BJT.

Next, gate oxide layer 160 and poly silicon layer 180 are sequentially stacked one above another on and/or over the entire surface of the semiconductor substrate and then, are patterned, thus forming first gate pattern 200a of the NMOS transistor on and/or over P-type well 120 of NMOS transistor region NMOS, second gate pattern 200b of the PMOS transistor on and/or over N-type well 140 of PMOS transistor region PMOS, and laminated layer 200c on and/or over trench dielectric layer 100b of BJT region NPN-BJT. In detail, gate oxide layer 160 is formed on and/or over the entire surface of the semiconductor substrate and in turn, poly silicon layer 180 is formed on and/or over gate oxide layer 160. Then, oxide layer 160 and poly silicon layer 180 are patterned. Thereby, first gate pattern 200a of the NMOS transistor is formed on and/or over P-type well 120 in a gate region of NMOS transistor region NMOS, second gate pattern 200b of the PMOS transistor is formed on and/or over N-type well 140 in a gate region of PMOS transistor region PMOS, and laminated layer 200c is formed on and/or over trench dielectric layer 100b of the BJT region NPN-BJT. Here, first gate pattern 200a, second gate pattern 200b and laminated layer 200c are formed simultaneously.

As illustrated in example FIG. 2B, N-type dopant is implanted into the P-type well 120 around NMOS gate pattern 200a, thus forming first LDDs 220 spaced apart from each other by the width of NMOS transistor gate pattern 200a. Also, P-type dopant is implanted into N-type well 140 around PMOS gate pattern 200b, thus forming second LDDs 240 spaced apart from each other by the width of PMOS gate pattern 200b. Next, dielectric material(s) are deposited on and/or over the entire surface of the semiconductor substrate including NMOS gate pattern 200a, PMOS gate pattern 200b and laminated layer 200c. By etching the deposited dielectrics, spacers 260 are formed respectively at the sidewalls of NMOS gate pattern 200a, PMOS gate pattern 200b and laminated layer 200c. Thereby, first LDDs 220 and second LDDs 240 overlap with spacers 260 of NMOS gate pattern 200a and PMOS gate pattern 200b.

As illustrated in example FIG. 2C, first photoresist patterns 280a, 280b are formed respectively on and/or over the PMOS transistor region PMOS including PMOS transistor gate pattern 200b and over a P-type junction region of laminated layer 200c. Next, N-type dopant is implanted using first photoresist patterns 280a, 280b as masks to thereby simultaneously form N-type junctions 300 in an N-type junction region of laminated layer 200c and N-type source/drain 320 in P-type well 120 of NMOS transistor region NMOS. In P-type well 120 of the NMOS transistor, N-type source/drain 320 of the NMOS transistor is formed at a greater depth than first LDDs 220. Also, the N-type dopant is implanted into the poly silicon layer included in NMOS gate pattern 200a during the N-type dopant implantation. After completion of the N-type dopant implantation, first photoresist patterns 280a, 280b are removed.

As illustrated in example FIG. 2D, second photoresist patterns 340a, 340b are then formed respectively on and/or over NMOS transistor region NMOS including NMOS transistor gate pattern 200a and on and/or over the N-type junction region of laminated layer 200c in which N-type junctions 300 are formed. Second photoresist patterns 340a, 340b may be formed on and/or over the entire surface of BJT region NPN-BJT except for the P-type junction region on and/or over which first photoresist pattern 280b is formed. Next, P-type dopant is implanted using second photoresist patterns 340a, 340b as masks, thereby simultaneously forming P-type junction 380 in the P-type junction region of laminated layer 200c and P-type source/drain 360 in N-type well 140 of PMOS transistor region PMOS. In N-type well 140 of the PMOS transistor, P-type source/drain 360 of the PMOS transistor is formed at a depth greater than that of second LDDs 240. Also, the P-type dopant is implanted into the poly silicon layer included in PMOS gate pattern 200b during the P-type dopant implantation. After completion of the P-type dopant implantation, second photoresist patterns 340a, 340b are removed. As the N-type dopant and P-type dopant are sequentially implanted into laminated layer 200c as illustrated in example FIGS. 2C and 2D, NPN-type BJT is formed in laminated layer 200c.

As illustrated in example FIG. 2E, a salicide process is then carried out to reduce the resistance of contacts 440 prior to carrying out a process of forming contacts 440. Prior to carrying out the salicide process, a plurality of salicide blocking layers 400 having a constant thickness is formed at boundaries between the different junctions of NPN-type BJT, to space the different conductive type junctions of NPN-type BJT from each other. Since embodiments adopts an NPN-type BJT, salicide blocking layers 400 are formed at boundaries between N-type junctions 300 formed in opposite sides of the BJT and P-type junction 380 formed in the center of the BJT. Next, the salicide process is carried out to deposit salicide metal on and/or over the entire surface of the semiconductor substrate and then a thermal heat treatment process is conducted on the deposited salicide metal. In this case, the salicide process is carried out using salicide blocking layers 400 as a mask. Accordingly, salicide layers 420 are formed on and/or over the respective junctions of the BJT, NMOS gate pattern 200a and N-type source/drain 320 of the NMOS transistor and PMOS gate pattern 200b and P-type source/drain 360 of the PMOS transistor. In particular, salicide layers 420 are formed on and/or over the poly silicon layers of NMOS gate pattern 200a and PMOS gate pattern 200b. After completion of the salicide process, salicide blocking layers 400 are removed.

As illustrated in example FIG. 2F, the inter metal dielectric layer is formed on and/or over the entire surface of the semiconductor substrate after completion of the salicide process. Next, a contact mask pattern is formed on and/or over the inter metal dielectric layer. As the inter metal dielectric layer is partially etched using the contact mask pattern as an etching mask, forming holes for formation of contacts 440 are formed in the inter metal dielectric layer. Next, contacts 440 are formed in the inter metal dielectric layer by burying the holes and performing planarization on and/or over an uppermost surface of the inter metal dielectric layer. In detail, contacts 440 are formed so as to be connected respectively to the respective junctions of the BJT, NMOS gate pattern 200a and N-type source/drain 320 of the NMOS transistor, and PMOS gate pattern 200b and P-type source/drain 360 of the PMOS transistor. Next, metal lines 460 are formed on and/or over the inter metal dielectric layer at positions corresponding to contacts 440 so as to be connected thereto.

Although the NPN-type BJT is described in accordance with embodiments by way of example, it will be appreciated that embodiments is also applicable to manufacture a PNP-type BJT via simple modifications in formation of photoresist patterns and dopant implantation processes. Further, in accordance with embodiments, no well or buried layer may be formed in the BJT region NPN-BJT as described above. As apparent from the above description, in accordance with embodiments, by forming a BJT used in a CMOS image sensor without using a well, it is possible to solve isolation between different conductive type wells due to formation of an NPN-type or PNP-type BJT derived from a well structure. Further, the BJT may be manufactured using CMOS processes and this advantageously enables the use of CMOS scaling.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
providing a semiconductor substrate having a junction transistor region, a first conductive well formed in a second conductive transistor region of the semiconductor substrate and a second conductive well in a first conductive transistor region of the semiconductor substrate; and then
simultaneously forming a device isolation layer at a boundary between the first conductive transistor region and the second conductive transistor region and a trench dielectric layer at the junction transistor region; and then
simultaneously forming a first gate pattern of a first conductive transistor over the second conductive well, a second gate pattern of a second conductive transistor over the first conductive well and a laminated layer over the trench dielectric layer having the same lamination configuration as the first and second gate patterns; and then
forming a bipolar junction in the laminated layer by sequentially implanting a first conductive dopant and a second conductive dopant into the laminated layer; and then
forming contacts connected to respective junctions of the bipolar junction.

2. The method of claim 1, wherein simultaneously forming the device isolation layer and trench dielectric layer comprises:
simultaneously forming a first trench at the boundary between the first and second conductive transistor regions and a second trench in the junction transistor region; and then
forming a dielectric layer in the first and second trenches.

3. The method of claim 1, wherein simultaneously forming the first and second gate patterns and the laminated layer comprises:
forming a gate oxide layer over the entire surface of the semiconductor substrate; and then
forming a poly silicon layer over the gate oxide layer; and then
patterning the oxide layer and poly silicon layer.

4. The method of claim 1, further comprising, after simultaneously forming the first and second gate patterns and the laminated layer and before forming the bipolar junction:
forming a first lightly doped drain (LDD) around the first gate pattern of the first conductive transistor by performing a first ion-implantation process using a first conductive dopant; and then
forming a second lightly doped drain (LDD) around the second gate pattern of the second conductive transistor by performing a second ion-implantation process using a second conductive dopant.

5. The method of claim 4, further comprising, after forming the first LDD and the second LDD:
simultaneously forming spacers over sidewalls of the first and second gate patterns and the laminated layer.

6. The method of claim 1, wherein forming the bipolar junction comprises:
forming a first photoresist pattern over a second conductive junction region of the laminated layer; and then
forming a first conductive junction in the laminated layer by implanting a first conductive dopant into the laminated layer using the first photoresist pattern as a mask; and then
removing the first photoresist pattern; and then
forming a second photoresist pattern over a first conductive junction region of the laminated layer in which the first conductive junction is formed; and then forming a second conductive junction in the laminated layer by implanting a second conductive dopant into the laminated layer using the second photoresist pattern as a mask; and then
removing the second photoresist pattern.

7. The method of claim 6, wherein forming the first photoresist pattern over the second conductive junction region of the laminated layer further comprises:
forming the first photoresist pattern over the second conductive transistor region.

8. The method of claim 7, wherein forming the first conductive junction in the laminated layer comprises simultaneously forming a first conductive source/drain in the second conductive well during implantation of the first conductive dopant using the first photoresist pattern as a mask.

9. The method of claim 6, wherein forming the second photoresist pattern over the first conductive junction region of the laminated layer further comprises:
forming the second photoresist pattern over the first conductive transistor region.

10. The method of claim 9, wherein forming the second conductive junction in the laminated layer comprises:
simultaneously forming a second conductive source/drain in the first conductive well during implantation of the second conductive dopant using the second photoresist pattern as a mask.

11. The method of claim 1, further comprising, after forming the bipolar junction in the laminated layer:
forming a salicide blocking layer having a constant thickness at a boundary between different junctions of the bipolar junction; and then
forming a salicide layer over the respective junctions of the bipolar junction by carrying out a salicide process using the salicide blocking layer as a mask; and then
removing the salicide blocking layer.

12. The method of claim 11, wherein forming the salicide layer comprises:
forming the salicide layer over the first gate pattern and a first source/drain of the first conductive transistor and the second gate pattern and a second source/drain of the second conductive transistor.

13. The method of claim 1, wherein forming contacts comprises forming the contacts so as to be connected respectively to the first gate pattern and a first source/drain of the first conductive transistor and the second gate pattern and a second source/drain of the second conductive transistor.

14. The method of claim 1, further comprising, after forming the contacts:
forming metal lines to correspond to the contacts.

15. The method of claim of claim 1, wherein the junction transistor region does not have a well formed.

16. A method comprising:
simultaneously forming a device isolation layer at a boundary between a first conductive transistor region having a second conductive well formed therein and a second conductive transistor region having a first conductive well formed therein, and a trench dielectric layer at a junction transistor region having no conductive well formed therein; and then
simultaneously forming a first gate pattern at the first conductive transistor region, a second gate pattern at the second conductive transistor region and a laminated layer at the junction transistor region; and then
forming a bipolar junction in the laminated layer by sequentially implanting a first conductive dopant and a second conductive dopant into the laminated layer.

17. A transistor of an image sensor comprising:
a semiconductor substrate having a junction transistor region having no well formed therein, a second conductive transistor region having a first conductive well formed therein, and a first conductive transistor region having a second conductive well formed therein;
a first conductive transistor formed over the second conductive well in the first conductive transistor region;
a second conductive transistor formed over the first conductive well in the second conductive transistor region;
a device isolation layer formed at a boundary between the first conductive transistor region and the second conductive transistor region;
a trench dielectric layer formed in the junction transistor region;
a junction transistor formed over the trench dielectric layer of the junction transistor region;
a bipolar junction formed in the junction transistor.

18. The transistor of claim 17, wherein the bipolar junction comprises:
a first conductive junction; and
a second conductive junction.

19. The transistor of claim 17, wherein the bipolar junction comprises an NPN-type junction.

20. The transistor of claim 17, wherein the bipolar junction comprises a PNP-type junction.
